(19) United States
(12) Patent Application Publication
(10) Pub. No.: US 2025/0035676 A1
(43) Pub. Date: Jan. 30, 2025

(54) POWER SENSING VIA QUANTUM PHENOMENON DETECTION

(71) Applicant: Wells Fargo Bank, N.A., San Francisco, CA (US)

(72) Inventors: Peter Bordow, Fountain Hills, AZ (US); Boris Beltinoff, Stanford, CA (US); Dale C. Miller, San Francisco, CA (US); Charlee Alexandra Stefanski, San Francisco, CA (US); Richard Orlando Toohey, Ithaca, NY (US)

(21) Appl. No.: 18/066,162

(22) Filed: Dec. 14, 2022

(51) Int. Cl. G01R 15/24; G01R 19/00; H02H 7/22; H02J 3/00

(52) U.S. Cl. CPC G01R 15/24; G01R 19/0092; H02H 7/22; H02J 3/0012

(57) ABSTRACT

Detecting a level of current in a conductor such as a power line can be accomplished using sensing devices that are coupled to the line. Such devices can have a clamshell or briefcase-style shape and close about the line. The line passes through a channel between the sides of the device. A quantum substance made of a material having a phonon decay sideband is arranged nearby the channel, and a light source and a scanning source work in tandem to cause the substance to emit light that can be analyzed to determine a magnitude of a magnetic field on the substance. By distributing such sensing devices about a grid or other electrical distribution network, current throughout the network can be collected and analyzed to ascertain the presence and location of interferences with the grid.

### BACKGROUND

Modern power distribution systems are inherently more complex than those that precede them. Modern power distribution systems can include distributed generation sources like wind or solar that are positioned at the downstream end of a power grid, and increasing electrification of devices, transportation, and infrastructure have increased the power transmitted through the power grid significantly. These power sources create new challenges in handling power.

Events that affect the performance of power grids have become more frequent, while simultaneously being more disruptive. For one example, wildfires that destroy power lines have increased in frequency and destructive power in recent years. In some instances, such fires are caused by the power grid itself, such as be over-burdening of aged power lines that causes overheating and drooping of the line until it is within range to cause combustion of nearby foliage. In addition to excessive power delivery on some lines, modern grids also may have to contend with power flow in unexpected directions. In some modern power grids, the use of distributed generation can cause “upstream” power flow in the direction from the conventional endpoints of the system towards the conventional power generation source. Some transformers, switches, and substations are not equipped for power flow in this unexpected direction, which can cause malfunction or failure of those components.

Furthermore, there has been an increasing recognition of power infrastructure as a target for sabotage or as part of infrastructure targeted during military conflicts. Because electrical systems are now such a crucial part of transportation, medical, and data and intelligence infrastructure, maintaining integrity of a power system even where parts are disrupted (due to intentional or unintentional interference) is increasingly important.

### SUMMARY

Embodiments are directed to detecting and addressing mechanical and electrical interference with a power distribution grid.

In a first embodiment, a sensing device for detecting a level of current in a conductor is described. The sensing device has a housing that includes a first half and a second half, wherein the first half and the second half are couplable to one another and define a channel therebetween. The sensing device includes a substance made of a material having a phonon decay sideband arranged in the housing adjacent to the channel, and a light source configured to emit a light at an energy level sufficient to excite electrons of the substance from a ground state to an energized state. The device further includes a scanning source configured to emit a scanning light, wherein the scanning light has a controllable wavelength lower than that of the light source. The device includes one or more focusing optics arranged to receive the light from the light source and the scanning light from the scanning source and direct the light and the scanning light to the substance. The device includes a photodetector arranged to receive light emanating from the substance and determine, based upon an intensity of the received light as a function of the controllable wavelength of the scanning light, a magnitude of a magnetic field on the substance.

The sensing device can include a power supply operatively connected to the light source, the scanning source, and the photodetector. The power supply can be one or more of a rechargeable battery, a replaceable battery, and a photovoltaic cell. The substance can be a nitrogen vacancy (NV) in a carbon diamond lattice. The scanning source can be a radio frequency (RF) source. The RF source can be controllable to emit wavelengths corresponding to the energy level between a ground state of an electron of the substance having spin ms=0 and an energy level of an electron of the substance having a non-zero spin. The energy level of the electron of the substance having a non-zero spin can include a range of energy levels, including both a first energy level of an electron having a spin ms=+1, and a second energy level of an electron having a spin ms=−1, wherein the first energy level is different from the second energy level in the presence of a magnetic field. A transmitter can be coupled to the photodetector to transmit a signal based on a sensed magnetic field at the substance. The device can include multiple NV centers.

According to another embodiment, a method for power grid management includes coupling a sensing device to a power transmission line. The sensing device includes a housing having a first half and a second half, coupleable to one another to define a channel around the power transmission line therebetween. A substance made of a material having a phonon decay sideband is arranged in the housing adjacent the channel. The method includes illuminating the substance with a light having an energy level sufficient to excite electrons of the substance from a ground state to an energized state. The method further includes illuminating the substance with a scanning light, wherein the scanning light has a controllable wavelength lower than that of the light, collecting an emanated light from the substance at a photodetector; and determining, based upon an intensity of the received light as a function of the controllable wavelength of the scanning light, a magnitude of a magnetic field on the substance created by the power transmission line.

The substance according to the method can be a nitrogen vacancy (NV) in a carbon diamond lattice. The scanning source can be a radio frequency (RF) source. The method can include controlling the RF source to emit wavelengths corresponding to the energy level between a ground state of an electron of the substance having spin ms=0 and an energy level of an electron of the substance having a non-zero spin. The method can include transmitting the magnitude of the magnetic field to a remote location. The method can include comparing the determined magnitude of magnetic field over a time period to a plurality of fingerprints. The method can include taking an remediating action to stabilize the power grid based upon the determination.

According to another embodiment, a system is disclosed for detecting mechanical or electrical interference with a power distribution grid. The system includes sensing devices arranged about the grid. Each sensing device includes a housing having a first half and a second half, wherein the first half and the second half of the housing are coupleable to one another to define a channel therebetween. A substance made of a material having a phonon decay sideband is arranged in the housing adjacent to the channel in each sensing device. A light source in each sensing device is configured to emit a light at an energy level sufficient to excite electrons of the substance from a ground state to an energized state. A scanning source in each sensing device is configured to emit a scanning light, and has a controllable wavelength lower than that of the light source. One or more focusing optics are arranged to receive the light from the light source and the scanning light from the scanning source and direct the light and the scanning light to the substance. A photodetector is arranged to receive light emanating from the substance and determine, based upon an intensity of the received light as a function of the controllable wavelength of the scanning light, a magnitude of a magnetic field on the substance. A central console is communicatively coupled to each of the plurality of sensing devices to receive the determination from each of the plurality of sensing devices, and a processor is configured to determine a network interference state by comparing the determination from each of the plurality of sensing devices and carry out an remediating action based on the network interference state.

In embodiments, each of the sensing devices in the system can have a port, and each port can be capable of either power transfer or data transfer or both. The network interference state can be detected by comparing the determination from each of the plurality of sensing devices to a database of fingerprints. The network interference state can be indicative of either or both of a mechanical interference and an electrical interference.

The details of one or more techniques are set forth in the accompanying drawings and the description below. Other features, objects, and advantages of these techniques will be apparent from the description, drawings, and claims.

### DESCRIPTION OF THE DRAWINGS

The following drawings are illustrative of particular embodiments of the present disclosure and therefore do not limit the scope of the present disclosure. The drawings are not to scale and are intended for use in conjunction with the explanations in the following detailed description. Embodiments of the present disclosure will hereinafter be described in conjunction with the appended drawings, wherein like numerals denote like elements.

FIG. 1 illustrates a power distribution grid according to an embodiment with sensing devices distributed throughout.

FIG. 2 illustrates a device with a quantum sensing device therein according to an embodiment.

FIG. 3 is an example method of diagnosing interference with a power distribution grid within the system of FIG. 1 using the sensing devices of FIG. 2.

FIG. 4 illustrates an example method of training a computer system to carry out the method of FIG. 3.

FIGS. 5-7 illustrate the quantum phenomena that are observable to measure magnetic field in the sensing device of FIG. 2 in one embodiment.

FIG. 8 is a perspective view of a sensing device according to an embodiment.

FIG. 9 is a perspective view of the sensing device of FIG. 9 in an open configuration.

FIG. 10 schematically shows example physical components of portions of the system of FIGS. 2, 8, and 9.

### DETAILED DESCRIPTION

Various embodiments will be described in detail with reference to the drawings, wherein like reference numerals represent like parts and assemblies through the several views. Reference to various embodiments does not limit the scope of the claims attached hereto. Additionally, any examples set forth in this specification are not intended to be limiting and merely set forth the many possible embodiments for the appended claims.

Whenever appropriate, terms used in the singular also will include the plural and vice versa. The use of “a” herein means “one or more” unless stated otherwise or where the use of “one or more” is clearly inappropriate. The use of “or” means “and/or” unless stated otherwise. The use of “comprise,” “comprises,” “comprising,” “include,” “includes,” and “including” are interchangeable and not intended to be limiting. The term “such as” also is not intended to be limiting. For example, the term “including” shall mean “including, but not limited to.”

An overhaul of the existing power grid to smart grid technology promises increased efficiency, better integration with renewables, increased security, shorter power outages, fewer fires, and reduced operator demands. To implement a smart grid, there will have to be technological advancements in many industries. This includes the deployment of improved sensors that provide the necessary information to implement a robust smart grid and inform the implementation of demand-side and supply-side solutions to grid challenges.

Existing technologies and techniques to address these problems can be categorized into two main groups: demand-side and supply-side. Supply-side solutions attempt to solve these problems through more sophisticated power generation techniques, while demand-side solutions attempt to manage use of power at the grid endpoints.

Supply-side solutions involve creating an appropriate amount of power at different locations throughout a grid to satisfy power demand while avoiding the problems described above. Supply-side solutions suffer from several challenges. For example, supply-side solutions cannot address upstream power flow from grid endpoints, such that utilities implementing supply-side solutions typically must still cap distributed power generation, even though distributed generation should reduce power distribution needs overall.

Supply-side solutions can also be expensive. Supply-side power grid management typically relies on multiple power generation mechanisms. The first among these is the base plant, which generates the bulk of the utility's power at a very inexpensive rate per unit of power generated. Additional demand on the grid is satisfied by layers of smaller power generators, down to “peakers” and capacitor banks. While these power sources can be rapidly engaged to satisfy demand, they can incur cost of over 100× the cost per unit of power generated compared to the base power plant.

Changing usage patterns in power grids has pushed utilities away from supply-side solutions. The so-called “duck curve” of power usage—in which power usage increases in the morning, dips in the midday as distributed solar provides power, and then spikes dramatically in the evening hours as the sun goes down and electric vehicles are plugged in—requires extensive use of peakers, capacitor banks, and other expensive power sources. Additionally, some solar grids, most notably in Hawaii, have had to cap installations of green power sources such as solar and wind to prevent upstream power flow, which supply-side solutions cannot solve.

Demand-side solutions are being implemented to address some of these problems. Demand-side solutions are useful to smooth power demand on a grid. For example, smart water heaters or electric vehicles can draw power at hours when demand dips. Flattening the power demand curve permits a utility to provide a greater portion of its power from a base station rather than expensive, smaller power sources. In some instances, such as using the battery system in an electric vehicle or home battery system, power can be stored during these times of low demand and re-injected into the grid at times of high demand, mimicking distributed generation to flatten the curve even further. Demand-side solutions can also be used to absorb excess distributed generation that would otherwise cause irregular power flow through the grid.

Demand-side solutions also suffer drawbacks, in that they require user adoption and can result in a poorer customer experience. A typical demand-side solution, automatic air conditioning shutoffs, causes the conditioned space to be less comfortable if used to heavily. Similarly, grid-connected water heaters may lack sufficient hot water during times of heavy power use. Some demand-side solutions may be effective for reducing immediate demand on a grid but increase overall power usage. For example, rapidly cycling an air conditioner unit may cause that unit to draw more power to cool a space, even though in the short term the power used by the air conditioner is decreased. Likewise, charging and discharging an electric vehicle or home battery system causes losses that would be better to avoid.

Both supply-side and demand-side solutions have benefits and disadvantages and are parts of a part of a holistic grid management system. It can be difficult, however, for a utility to know which solutions are the most appropriate in a particular circumstance because measuring the voltages, currents, temperatures, and other conditions on different components of a grid at any given time is difficult and expensive. There have been numerous examples in the past several years in which a utility's power disruption is caused by a fire that happened because of a hot, drooping power line. With enhanced detection of the drooping line, an appropriate solution could be implemented that would address the power routing (i.e., implement a supply-side solution within the grid) or reduce instantaneous load (i.e., implement a demand-side solution within the grid). Similarly, a utility could benefit from more rapid and accurate detection of current throughout the grid to determine when power is likely to begin flowing upstream, such that additional loads could be activated to sponge the additional power (i.e., implement a demand-side solution) or a relatively downstream power source can be shut off (i.e., implement a supply-side solution).

The conventional solution for detecting electrical parameters along a grid uses synchrophasers. In most power grids, power is transmitted in three phases, each out of phase with the other two by 120 degrees. To detect conditions throughout the grid, for each phase of a 3-phase system, two tap-in points are needed and a system of transformers are provided. The synchrophasers compare the signal in each line against one another as well as against a clock to obtain useful information about the grid. The synchrophasers themselves are “in-line” with the power lines, however, and also require constant power themselves. Thus damage or outage of synchrophasers can cause outages themselves, and a malfunctioning synchrophaser can fail in dramatic fashion, causing heat or even sparks or fire when they fail. Replacing a synchropher is relatively dangerous, again because they are in-line with the live wires at very high voltage.

Thus there is a need to better monitor the status of a power grid to increase knowledge while decreasing the complexity and danger level associated with deploying synchrophasers. Notable limitations of synchrophasors include their requirement for a three-phase electrical connection, and accompanying requirement to use six electrical connections and two transformers to take their measurements. Another limitation of synchrophasers is their requirement for a direct connection to the power grid, which adds danger for technicians and introduces points of failure. Synchrophasors require networking with a standard clock to measure phase difference, this adds an external reference point and adds complexity

While the paragraphs above relate to power grid solutions, it should be understood that there are a variety of environments in which improved intelligence about the status of an electrical distribution system could be advantageous. For example, similar solutions could be valuable within a data storage facility, a nuclear power facility that requires external power delivery, a medical facility, or any of a variety of other contexts too numerous to list here in their entirety.

Generators transmit the electricity within the grid using Alternating Current (AC) at very high voltage, often exceeding 300 kV, over large distances. This power is then stepped down using a transformer to about 100 kV for large consumers such as manufacturing facilities or further subtransmission. Power can be stepped down several more times for various levels of consumers, reaching households at 120V in North America. In different regions and countries as well as for different types of end user, the final voltage may vary, typically between about 100V and about 240V. Similarly, mains power frequency can vary depending on the location, typically between about 50 Hz and about 60 Hz. In some circumstances, a load or user may require a different input, such as a DC power supply or a different voltage or frequency from the mains frequency. Such demands can be satisfied using combinations of transformers and rectifiers.

The current required to transmit a given power is inversely proportional to the voltage, thus very high voltages are necessary to minimize power losses over large distances. These losses increase with the amount of current flowing through the transmission lines and their length, among other factors. The AC is used as method of electricity distribution in most countries mainly because the AC transformation stations used to step up and down the voltage have very simple construction, in contrast to high-voltage direct current equipment, which is complex, expensive to build, and costly to maintain.

Improvements to current or magnetic field sensing are described herein that make use of materials with detectable Zeeman effect. The Zeeman effect is a quantum effect of materials that provides a measurable optical output as a function of applied magnetic field. Zeeman is a particularly useful mechanism to detect features of a power distribution system that operates at high voltage, such as a power distribution grid, where current is typically low such that conventional current sensors are inaccurate. A Zeeman sensor can be arranged next to or on a power line and still exhibit a strong measurable effect from the high voltage AC signal at low current levels.

### Zeeman Effect

The Zeeman effect is a quantum effect that can be used to measure magnetic fields, as briefly described above. Electrons within an electron shell are categorized into quantum numbers n, l, mₗ, and mₛ. The last two of these, mₗ, and mₛ, refer to angular momentum (which can be an integer between-n and +n, where n is an integer based on the size and complexity of the atom or shell) and spin (which can be either +½ or −½), respectively.

It is a fundamental principle of quantum mechanics that no two electrons within an atom or electron shell can have identical n, l, mₗ, and mₛ numbers. In other words, while two electrons may have the same values of n, l, and mₗ, those two electrons will necessarily have opposite spin values: one will be +½ while the other will be −½.

The Zeeman effect is the resulting phenomenon that is a necessary outcome of this principle. As a magnetic field is applied to a light-emitting material, the emitted light will have a wavelength that is dependent upon the quantization of angular momentum and the spin state of the electrons. That is, lines at a wavelength corresponding to each quantized angular momentum value will appear, and these lines are split into two finely-spaced lines based because of the two spin states of the electrons within that angular momentum value. As the electric field is increased, the spacing of these lines increases in proportion.

Although the Zeeman effect is referred to throughout this document, it should be understood that the desired effect (specifically, detection of attributes of a power line) could be accomplished equally using substances that exhibit the inverse Zeeman effect. That is, the properties of the power line such as operating voltage, frequency, or physical movements can be detected not as fluorescence in multiple bands but rather as absorption in multiple bands. Similarly, it is contemplated that for some implementations the Stark effect or inverse Stark effect could be used to detect such properties of a power line by detecting corresponding properties of the electrical field at an adjacent detection device as described in more detail below. Throughout this disclosure, unless otherwise specified, it should be understood that Zeeman, inverse Zeeman, Stark, and inverse Stark effects can be used interchangeably.

### Stimulated Fluorescence

Some materials exhibit more exaggerated Zeeman effect than others. One commonly used substance, used throughout the remainder of this disclosure, is the nitrogen vacancy (NV) center, though the Zeeman effect can be observed in other compounds and materials that can be used in place of NV centers in various embodiments.

The NV center is a class of solid-state defects in a diamond lattice known as color defects. The NV center is of interest within quantum information because it has a long spin coherence time, is operational at room temperatures and pressures, and is easily manipulated and observed optically with an off-resonant laser.

NV centers are a substitutional defect. A nitrogen atom replaces one of the carbon atoms in the diamond lattice and is accompanied by an adjacent vacancy. Due to the trigonal symmetry of the diamond lattice, the NV Center has 4 possible orientations. In a diamond sample we can either observe and manipulate a single NV center or have an ensemble of NV centers randomly distributed in the sample. Single centers have higher resolution measurements but can be more difficult to produce. Ensemble samples are cheaper, but their signal has a lower resolution due to the orientation averaging. Either single NV centers or ensemble NV centers can be used in various embodiments described in more detail below.

There are many stable charge states of NV centers that can be used. Most quantum information uses NV\hat{ }−, a negatively charged NV center. This has a spin 1, triplet ground state. The spin sublevel energy structure of the ground state is given by a projection of the electronic spin state along the nitrogen-vacancy axis. The mₛ=0 state has the lowest possible energy; this is split from the mₛ=±1 state by a field splitting energy of D=h*2.87 GHz. The mₛ=±1 state is degenerate, but applying an external field lifts the degeneracy, forming a subspace of mₛ=0 and either mₛ=1 or mₛ=−1 which can be used as a qubit.

NV centers are popular for industrial applications because they are operational at room temperatures and are versatile for many uses in industry. Most uses of NV centers use a two-laser system to probe the atomic structure of the NV site in the diamond crystal. By observing how the diamond fluoresces, it is possible to learn about the state of the atoms at the NV center and how they change over time. This is called stimulated photoluminescence.

Stimulated fluorescence is by no means a phenomenon isolated to NV centers. Although NV centers provide a convenient mechanism for measuring stimulated fluorescence, other materials and structures can be used. For example, it is contemplated that silicon-based materials could be used and function quite well in lieu of the NV center in a diamond discussed above. A non-comprehensive list of materials that are usable in various embodiments include Xenon, Cr: forsterite, as well as defects in crystal structures such as silicon-vacancy defects, germanium-vacancy defects, tin-vacancy defects, and lead-vacancy defects. Other, non-optical methods of detecting the Zeeman effect are known that could be used in alternative embodiments. Any suitable alternate quantum material can be used to measure energy states, though optical methods are some of the simplest.

### Field Detection

In electrical power delivery systems such as power grids, server power busbars, or high voltage wiring to or from large loads or power sources, there are often an array of high voltage lines. As described above, these lines are often run at high voltage with low AC current to facilitate power distribution with relatively low losses.

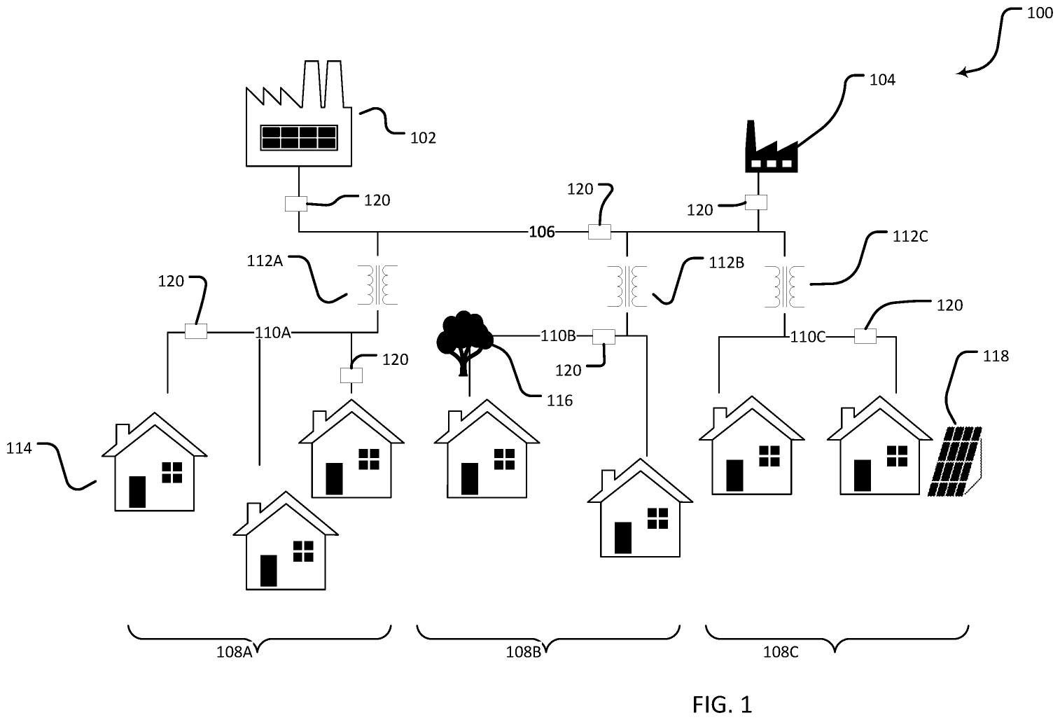

FIG. 1 depicts one such system, in this case a simplified power distribution grid 100. Power distribution grid 100 is shown as a system of residential power mains, but in various embodiments power distribution grid 100 could be any of a variety of systems such as those that deliver or receive power to or from server banks, financial institutions, offshore power generation facilities, or the like.

Power distribution grid 100 includes a power plant 102 and other, smaller, more expensively-operated peaker plant 104. In many power distribution systems, a base plant (e.g., power plant 102) provides the majority of electricity within the grid, while a smaller plant (e.g., peaker plant 104) can be operated in times of peak usage or when there is a sudden ramp up in demand for electricity. Peaker plant 104 may be more responsive to requests for power, but relatively more expensive to operate. Other systems not shown in FIG. 1 can be implemented such as capacitor banks, battery banks, and a variety of different power plants that use different fuels with different costs, startup and shutdown times, and power production capacity.

Power plant 102 and peaker plant 104 are connected to high voltage line 106. High voltage line 106 can be, for example, a high-voltage long-distance transmission line. In some embodiments of power distribution grid 100, a step-up transformer (not shown) may be used to raise the voltage provided by power plant 102 and peaker plant 104 to be at the appropriate voltage for high voltage line 106. High voltage lines are typically operated at between about 200-500 kV, though with power being transported across longer distances and higher overall energy usage with increasing electrification, this typical operating voltage may increase over time.

High voltage line 106 is in turn coupled to multiple subdivisions 108A, 108B, 108C. Each of these subdivisions 108A, 108B, 108C has a corresponding low voltage distribution line 110A, 110B, 110C, respectively, fed from the high voltage line 106 by a transformer (112A, 112B, and 112C, respectively). The low voltage distribution lines 110A, 110B, 110C are operable at the appropriate voltage for use in residential or commercial loads 114 within the corresponding subdivision 108A, 108B, 108C. For purposes of this explanation, discussion of multi-phase power is omitted, though it should be understood that in some instances a low voltage distribution line 110A, 110B, or 110C can be operated in such a way that different loads 114 connected thereto can operate at higher voltage than that of the individual low voltage distribution lines 110A, 110B, or 110C taken individually.

Hazards and power outages can be caused by conditions that interfere with the normal flow of power from the generation end (e.g., from power plant 102 and peaker plant 104) to the other (e.g., to loads 114). Some examples of such conditions can be interactions with trees 116, or distributed generation 118. Both of these are expected parts of operating a power distribution grid 100, and detecting, measuring, and managing such conditions and others is a critical part of operating a modern electrical grid.

Trees 116, or other obstructions or interfering objects, can short out power lines, or rub against lines over time causing damage to the insulation thereon or the conductor itself. In some circumstances, trees 116 and other similar objects like bushes are flammable such that shorting or arcing of the line due to this type of interference can start fires, disrupting power service and also creating other hazards. In addition to trees 116, other natural or manmade structures can mechanically interfere with power lines, such as drooping gutters or leaning buildings.

While trees 116 depict one common type of mechanical interference with power lines, they are representative of this broader category of mechanical interferers that cause displacement, wear, or destruction of power lines. In some cases, this type of interaction with the power distribution grid 100 can be the result of no external interference whatsoever, but instead be due to behavior of the power line itself. For example, a drooping or sagging power line that is overheated may drape across some other structure, or to the ground, creating hazards. Likewise, a tipping power pole due to an old pole, an unstable foundation, or extreme wind or other weather, may cause mechanical interference. Trees 116 in FIG. 1 therefore are just one example among a category of hazards that result from mechanical interactions with power lines. This category of hazards can include both inadvertent interference (e.g., from trees 116 or aging infrastructure) or intentional interference (e.g., sabotage, illicit power line tapping).

Distributed generation 118 can also cause disruption to power distribution grid 100. In FIG. 1. distributed generation 118 is located in subdivision 108C and reduces load on low voltage distribution line 110C. Distributed generation 118 can include solar, wind, or other types of generation that occur at the endpoint of the power distribution grid 100.

In some circumstances, an excess of distributed generation 118 can create grid instability by raising the voltage of low voltage distribution line 110C, increasing the frequency of low voltage distribution line 110C, or causing power flow “upstream” (i.e., through transformer 112C back towards high voltage line 106). Each of these can cause faults, such that utilities commonly restrict the amount of distributed generation 118 that can be installed on a particular portion of a power distribution grid 100. Increasingly, technologies exist that could absorb this excess capacity when it exists, such as electric vehicles, whole-house batteries, or grid-connected smart electric water heaters, but doing so requires that the excess capacity be detected and that these demand-based responses be implemented in a timely fashion.

Distributed generation 118 is only one example of a category of electrical disruptions that can occur in a power distribution grid 100. Like trees 116 depicted only one common type of mechanical interference with power lines, distributed generation 118 is representative of a broader category of electrical interferers that cause disruptions in power distribution. In some cases, this type of interaction with the power distribution grid 100 can be the result of a short in a power line, such as arcing or a downed line connected to a conductor. Electromagnetic interference, such as from solar flares or electromagnetic pulses, can similarly create electrical interference. Distributed generation 118 in FIG. 1 is therefore just one example among a category of hazards that result from electromagnetic interactions with power lines. This category of hazards can include both inadvertent interference (e.g., from solar flares or excess distributed generation) or intentional interference (e.g., electromagnetic pulses, power grid hacking).

For both mechanical disruptions (e.g., trees 116) and electromagnetic disruptions (e.g., excess distributed generation 118 on a particular portion of the power distribution grid 100) service can be enhanced and hazards can be reduced by knowing more about what is occurring at any particular portion of the power distribution grid 100. Relevant information that can improve these aspects of power distribution grid 100 include the voltage, frequency, location in the grid, and also physical movement or displacement. Conventionally, only some of these could be known, and only at limited locations, through the implementation of synchrophasers and the like.

In FIG. 1, sensing devices 120 are shown distributed throughout various portions of power distribution grid 100, including on high voltage line 106, on low voltage distribution lines 110A, 110B, 110C, and even at other locations such as nearby particular loads (e.g., 114), upstream power generation sources (e.g., 102 and 104), and downstream power generation sources (e.g., 118). In embodiments of power distribution systems like power distribution grid 100, sensing devices 120 could be arranged as desired to get relevant information where the operator of that system expects some kind of mechanical or electrical disruption is likely to occur. Alternatively or in combination with such placement, an operator of a power distribution system like power distribution grid 100 could place sensing devices 120 at regular intervals along runs of power lines, or they could be placed randomly. In still further embodiments, a power grid could be analyzed either manually or using a trained machine learning algorithm to predict areas where sensing devices 120 could more accurately or rapidly detect mechanical or electromagnetic disruptions to power distribution grid 100.

Over the last few years there has been a drive for more accurate sensing techniques. Advances in facial recognition, self-driving cars, GPS, and many other emerging technologies all rely on advancements in sensor technology. Many recently-developed sensors are quantum sensors. Quantum sensors exploit quantum mechanics to outperform classical sensors. Specific devices that can be used as sensing devices 120 are described in more detail below, in which quantum sensing provides advantages over conventional sensor technologies. For purposes of description of FIG. 1, however, it will suffice to say that sensing devices 120 are capable of and configured for detection of the characteristics described above that are useful in diagnosing mechanical and electromagnetic disruptions to power distribution grid 100. In embodiments, sensing devices 120 can detect one or more (or all) of current, voltage, frequency, location on the grid, and more precise local displacement of the sensor such as due to a drooping line or interaction of the line with a tree branch.

In some embodiments sensing devices 120 can be arranged pervasively throughout a grid, such as between each set of power poles in an otherwise conventional low-voltage power main. In such embodiments, the location of a disruption can be determined with a very high level of precision, and very rapidly.

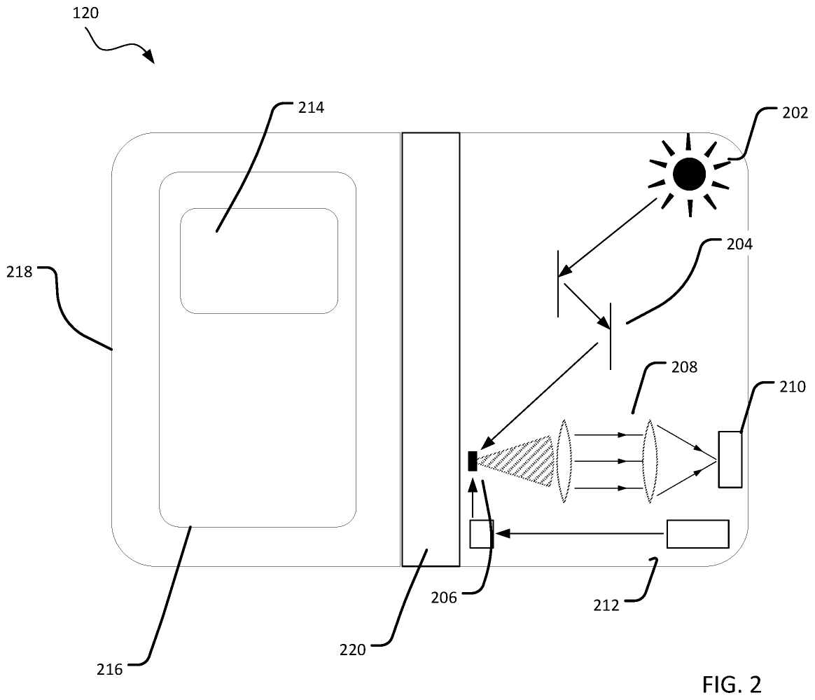

FIG. 2 shows one example of a sensing device 120 that can be implemented in such systems (e.g., as sensing devices 120 in FIG. 1). Sensing device 120 uses quantum sensing to detect parameters related to the operation of a line to which it is attached.

Sensing device 120 includes a light source 202, focusing optics 204, a quantum structure 206, collecting optics 208, a detector 210, a pulse generator 212, a power supply 214, and a circuitboard 216. The light source 202, focusing optics 204, quantum structure 206, collecting optics 208, detector 210, pulse generator 212, power supply 214, and circuitboard 216 are all arranged in a housing 218 having a central channel 220.

Sensing device 120 includes a quantum sensor therein and can detect levels changes to the signal passing through a cable (not shown). In embodiments, sensing device 120 not only detects aspects of the signal passing through a cable, but can also process that data to diagnose operating conditions and possible interference with the functioning of the power line. Additionally, sensing device 120 may be capable of transmitting the corresponding data, or a diagnosis, or both, to a remote location such as a central console operated by a utility or other such entity for appropriate action, or for comparison to data from other sensing devices like 120 that are situated in other portions of a power distribution network.

Light source 202 provides light at a desired wavelength. Light source 202 can be, for example, a laser or a diode, and can be tuned to a predetermined wavelength.

Focusing optics 204 are shown in a simplified form and are arranged to direct light provided by light source 202 towards quantum structure 206. In other embodiments there may be more or fewer focusing optics 204 arranged between light source 202 and quantum structure 206, and they may take the form of any combination of mirrors, lenses, dichroics, filters, or objectives. In some embodiments, focusing optics 204 may be omitted altogether, such as when light source 202 can independently be focused or targeted towards quantum structure 206. Light source 202 could also be a diffuse light source and provide sufficient light to quantum structure 206 to obviate the need for focusing optics 204 in some embodiments. Although focusing optics 204 can be used to direct all the light to the quantum structure 206, such as using lenses or mirrors with a focal point coinciding with the quantum structure 206, in other embodiments focusing optics 204 may only direct some portion of light toward quantum structure 206, and the focal point (if any) of such optics may not exactly coincide with the location of quantum structure 206.

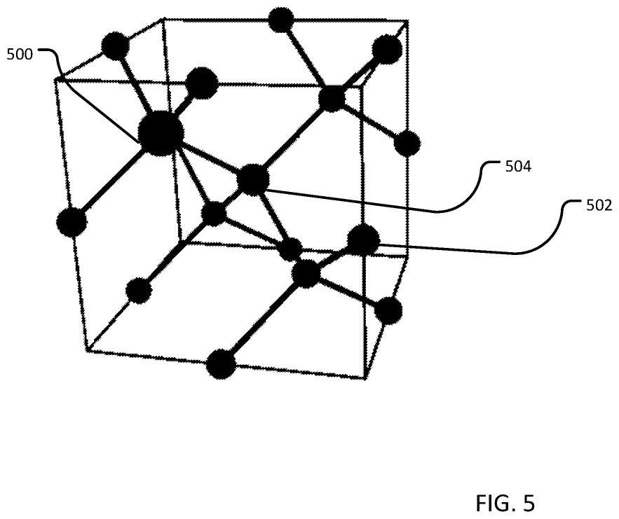

Quantum structure 206 is made of a material that exhibits a quantum effect, such as the Zeeman effect, inverse Zeeman effect, Stark effect, or inverse Stark effect as described above (again for simplicity, these will all be referred to by reference to the Zeeman effect going forward). In one example, quantum structure 206 is a Nitrogen Vacancy (NV) in a lattice, as described in more detail below with respect to FIG. 5A.

Light source 202 and quantum structure 206 are selected to be compatible with one another, in that light source 202 can be used as an optical pump on quantum structure 206. In other words, light source 202 can be an off resonant light source that prepares all electrons in quantum structure 206 into a ground state. Light emitted from quantum structure 206 is collected by collection optics 208 and directed to detector 210. Pulse generator 212 can be an RF generator in some embodiments, and can include sub-components such as amplifiers or switches to direct RF signal to the quantum structure 206.

Power supply 214 and circuitboard 216 are shown for illustrative purposes, as various components described herein may require power to operate. Power supply 214 can be a battery, capacitor, or the like, or can include power generation features such as one or more solar cells or capability to draw line voltage. Circuitboard 216 likewise can be any of a variety of structures that control the operation of the light source 202, detector 210, and pulse generator 212, and additionally collect data from detector 210. As described above, the data from detector 210 can be analyzed at the sensing device 120 itself in embodiments, and optionally stored on a memory (not shown) that can be coupled to or a part of circuitboard 216. Additionally or alternatively, circuitboard 216 can include or be coupled to a transmitter (not shown) that routes data from sensing device 120 to a remote location. It is envisioned that this will be a typical configuration for such devices, so that data from multiple sensing devices 120 can all be transmitted to a common location for analysis, which will improve the ability of the operator of an electrical distribution system to detect patterns across the larger network that could indicate potential failures, maintenance opportunities, or power- or cost-saving opportunities. Such transmitters (not shown) could use wireless network data, Bluetooth, mesh network technology, transmission along the power lines themselves, or any of a variety of other wired and wireless data transmission networks or protocols.

Transfer of power and data can be accomplished by directly accessing the sensing device 120 in some embodiments. For example, sensing device 120 may have a memory (not shown) coupled to circuitboard 216 that collects data measured at detector 210. This data can be collected by connecting to sensing device 120 either with a wired connection (such as a USB port, not shown) or wireless connection from an operator passing by the sensing device 120. Similarly, power can be provided by replacing or recharging a battery that is a part of power supply 214 either via a wired connection or wirelessly. For areas where power or data cannot easily by transmitted or obtained, servicing sensing device 120 in this way can be advantageous. Often sensing device 120 will be mounted at a high altitude or otherwise in a location that is difficult to access, and there can be advantages to configuring sensing device 120 to be serviced by a drone. For example, an externally accessible battery, data storage device, or both can be used so that a drone can remove, replace, or recharge one or both of these as needed.

Housing 218 contains the components of sensing device 120 described above. Housing 218 is shown as roughly rectangular in cross-section, having central channel 220 arranged down the middle thereof. The overall dimensions of housing 218 could vary in other embodiments, as well as the position of central channel 220 therein. For example, housing 218 could have a clamshell shape, or a circular cross-section. Central channel 220 circumscribes the power line on which sensing device 120 is installed, and it may be beneficial depending upon the type of power line to configure housing 218 so that it can clasp or engage with an appropriate power line without causing damage or obstruction.

As shown in FIG. 2, central channel 220 is adjacent quantum structure 206. Quantum structure 206 should preferably be arranged within range of a power line to detect electromagnetic field levels emanating therefrom that provide insights into the functioning of the power line. Therefore it may be preferable to arrange the quantum structure 206 close to the power line because such fields dissipate in relatively short distances from the line itself, often making readings too weak to be usable after 1 cm or less from the insulative sleeve of the power line. In embodiments, housing 218 may have a gap or opening so that quantum structure 206 can be positioned even closer to the central channel 220 and therefore the power line to collect data using even stronger fields, by avoiding having the intervening structure of the housing 218.

Central channel 220 could, in alternative embodiments, be non-central, or could even be on the outside of housing 218. Proximity of quantum structure 206 to the electrical transmitter (e.g., power main, high-voltage transmission line, or the like) can be accomplished through appropriate positioning of the quantum structure 206 within the housing 218. Housing can be any of a variety of corresponding structures, such as a unitary piece that clips on or is otherwise fastened to an electrical transmitter. In other embodiments housing 218 can be a clamshell design or the like that encloses an electrical transmitter within a channel like central channel 220.

In an alternative embodiment, each of the structures shown in FIG. 2 are miniaturized into a bespoke or customized chip. For example, each of the structures shown in FIG. 2 could be implemented in a photonic chip. Photonic chips are quite small and versatile, and could be affixed directly to an electrical conductor rather than enclosing the conductor therein. A photonic chip as envisioned could include the quantum structure 206 on one face thereof, and could be attached to a clamp, adhesive, or other fastener to have that face put in direct contact with the electrical line.

Sensing device 120 is one example of a device having a quantum sensor that can provide highly accurate and timely information regarding the status of a corresponding electrical transmission line, such as for use in the power distribution grid 100 of FIG. 1. Electrical mains and high-voltage transmission lines can be monitored without tapping into the conductors themselves. This is accomplished through the arrangement of quantum structures in proximity to such conductors and detecting field strength and pattern indicative of the power flow therein. Conventional, non-quantum sensors such as open-loop and closed-loop Hall sensors have not been implemented in this way because of Hall element offset and drift Additionally, since Hall sensors only respond to static magnetic field, they are not well suited to AC current sensing, especially in sensors that have any hysteresis curve. Inductive sensors can also be used to detect magnetic field, but typically have low enough sensitivity that they are unusable or inaccurate for the low currents used in industrial power transmission. Quantum sensors rely on fundamental quantum physics, such as atomic transitions, so they do not drift nor require recalibration, can sense alternating field as easily as static field, and are usable to detect very low current levels.

Quantum structure 206 exhibits either emission or absorption that is a function of electromagnetic field incident thereupon. In one embodiment, quantum structure 206 is a carbon diamond having NV defects. NV centers are popular because they are operational at room temperatures and are versatile for many uses in industry. Most uses of NV centers use a two-laser system to probe the atomic structure of the NV site in the diamond crystal. By observing how the diamond fluoresces, the state of the atoms and how they change over time can be measured. This technique is called stimulated photoluminescence.

### Deployed Systems and Pattern Recognition

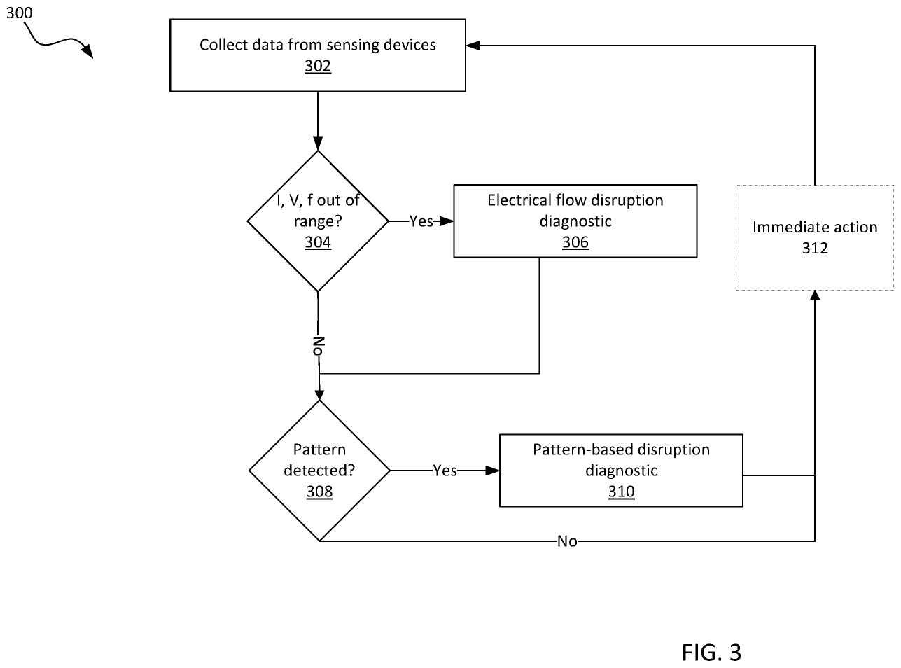

FIG. 3 illustrates a method 300 for diagnosing disruptions to a power distribution system like the one shown in FIG. 1. Data is collected from sensing devices (e.g., sensing devices 120 of FIG. 1) at 302. The data collected at 302 can be, for example, voltage, frequency, current, or movement or displacement of a power transmission line (e.g., 106, 110A, 110B, or 110C of FIG. 1). In embodiments, the collected data at 302 can be an indication of one of these parameters, rather than measuring the parameter directly. For example, current in an AC line can be ascertained by measuring the magnetic field generated by the AC current at a known distance from that AC line. Similarly, because movement of charges creates electromagnetic fields, displacement of a powered line creates a corresponding detectable change in the field nearby the line that can be used as an indirect indication of the displacement parameter.

Sensing devices (e.g., sensing devices 120 of FIG. 1) can therefore use quantum sensors to detect parameters—whether directly or indirectly—that give the value or change over time in current, voltage, frequency, or displacement of the line. As shown in FIG. 1, such sensing devices 120 can be arranged throughout a power distribution grid 100 so that the current, voltage, frequency, or displacement of various specific locations therein can be known. Collecting data from sensing devices 302 can include collecting data from just one such sensor, or from multiple sensing devices within the system. In embodiments, most or even all of the data from sensing devices within a system can be collected at 302.

At 304, current, voltage, and frequency are compared to predetermined values or ranges. For example, line voltage on a high voltage power line may be expected to be 200 kV but, when measured, may be 190 kV. Such a measurement would be an indication that the system was not functioning as intended.

Depending upon the circumstances, at 306 it may be appropriate to address such a measured value by implementing supply-side or demand-side solutions to balance the power distribution system. Alternatively, it may be determined that the reading is due to mechanical or electrical interference with the line or a connected part of the distribution system and other remedial actions like tree trimming, power re-routing, or equipment repair or replacement can address the anomaly. Performing a diagnostic at 306 can include comparing the data collected at 302 to historical data, or to expected values, or to other sensor data that can explain why the value differs from the value or range that was expected.

At 308, pattern detection is performed. Pattern detection uses data collected at 302 and determines whether there are oscillations, spikes or troughs, anomalies with periodicity, or other patterns that may indicate a current or incipient mechanical or electrical interference that is likely to affect the electrical distribution system. Current mechanical or electrical interference can include, for example, downed lines, hacking, over-generation of distributed generation, and fires. Incipient mechanical or electrical interference can include, for example, tree branches intermittently touching a line and causing “blinking” voltage drops, decreasing voltage from insufficient generation, or sagging of power lines that often precede down lines or fires.

In a system with sensing devices deployed throughout (as shown in FIG. 1, for example), patterns can be identified that are based on the sensed data at 302 from multiple sensing devices. For example, if multiple sensing devices are positioned on a single low voltage line (as shown in subdivision 108A of FIG. 1, in which two sensing devices 120 are both on low voltage distribution line 110A) the output of one of the sensing devices can be compared to that of the other sensing device on that same line to provide pattern data. Other comparisons that may yield valuable information about the functioning of the overall system will be readily recognized by those of skill in the art. A non-exclusive list of such comparisons may include sensing devices on either side of a transformer, multiple sensing devices on loops that could be affected by electromagnetic interference, sensing devices that are supported by the same physical infrastructure such as a shared power pole or transmission line, or sensing devices near distributed generation sources.

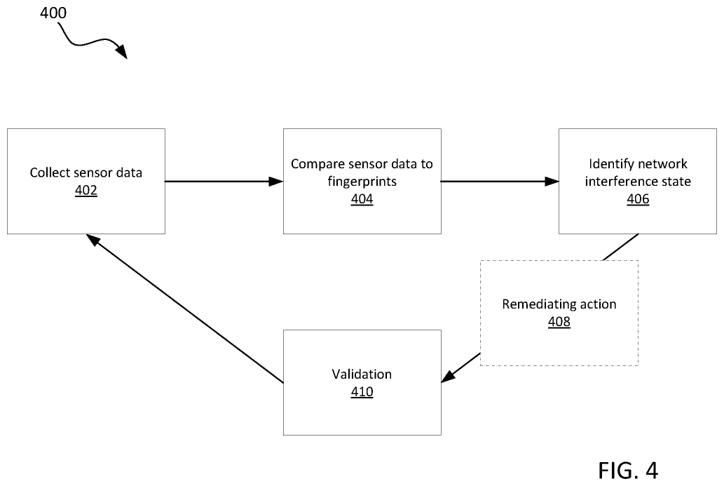

At 310, the pattern is diagnosed to determine if it is indicative of such a disruption or potential disruption. This type of diagnostic is described in more detail with respect to FIG. 4. Depending upon the outcomes of the electrical flow disruption diagnostic 306 and the pattern-based disruption diagnostic 310, a remediating action 312 may be warranted. Such remediating action 312 may constitute, for example: dispatching firefighting services, dispatching tree trimming services, rerouting power to supplement or avoid a particular portion of a power grid, or alerting law enforcement to hacking or sabotage attempts.

While FIG. 3 shows one example system for handling a power distribution system having quantum sensors, the out-of-range detection (304) and pattern-based detection (308) need not be performed sequentially. Either 304 or 308 could be performed before or after the other, or they could be conducted sequentially. In some embodiments, only 304 and 306 will be conducted after collecting data at 302, while 308 and 310 are omitted. In others, only 308 and 310 will be conducted after collecting data at 302, while 304 and 306 are omitted.

FIG. 4 shows an example of a fingerprint-based mapping system 400 that can be used to diagnose power distribution system disruptions as described with respect to FIG. 3.

At 402, sensor data is collected as described with respect to FIGS. 1-3. Sensor data collection at 402 can be by a single sensor, or by a set of sensors or one or more sensing devices. Data from the sensor, sensors, or sensing devices is compared to “fingerprints” at 404. Comparison of sensor data to fingerprints at 404 can involve fitting the sensor data acquired at 402 to expected outputs for a normally-functioning networks, grids, or power lines. Such fingerprints can be stored in a fingerprint database.

Fingerprints stored in fingerprint database can include signal that would be expected in the event of common failure modes. For example, a tree branch brushing against a power line may cause a recognizable, semi-periodic signal as a result of movement of the line (since movement of charge carriers creates electromagnetic field). As the branch grows or interferes more substantially with a power line, the signal may change and correlate better to a different fingerprint. Other fingerprints corresponding to various mechanical or electrical interference types and degrees can be stored in the fingerprint database.

In embodiments, a fingerprint database can include more than static or snapshot-style fingerprints. Fingerprint databases can include fingerprints that identify failures based on individual sensor output change over time, periodicity, or trends, for example. Fingerprints within a fingerprint database that are compared to sensor data at 404 can be based on magnetic field or electric field, either directly or used as a proxy for current or frequency or voltage in the electrical conductor, or some combination thereof.

Based on the comparison at 404, a network interference state can be generated at 406. The network interference state generated at 406 can be indicative of the types of mechanical and electrical interferences described above. The network interference state generated at 406 may be that the line is operating within normal parameters—that is, that there is no identifiable network interference. Alternatively a network interference state may be generated at 406 that, based on a match between sensed data at 402 with a fingerprint from a fingerprint database during the comparison 404, a tree branch is rubbing against a power line at a specific location near to a particular sensing device.

Based upon a network interference state generated at 406, a remediating action may optionally be taken at 408. As described above, there are circumstances in which a network interference state 406 is indicative of a time-sensitive hazard such as an existing or imminent fire or exposed live wiring, which would justify remediative action such as turning off power or re-routing it until the situation can be assessed further. Some remediating actions at 408 may require human intervention, while others may not. For some hypotheses at 406, an remediating action 408 could include automated deployment of a drone or other similar system to collect more information.

The additional information could be photographs of the site of a suspected hazard or upcoming maintenance need. Remediating action 408 can be scheduled, rather than being conducted instantaneously. For example, after a strong storm there may be multiple hypotheses 406 indicating interference between various power lines and trees. Of these, there may be hypotheses generated at 406 that are indicative of a high level of risk (such as a risk of fire or live wires exposed to the public), other hypotheses generated at 406 that show outages or abnormal levels of power delivered to a subdivision of the overall power distribution system, and still others that are relatively low-priority maintenance needs such as a tree branch that is touching a power main but not yet creating any imminent risk of causing an outage or a hazard. These types of interference can be prioritized, and human or robotic resources to diagnose or repair these issues can be deployed according to sets of rules that enhance safety and reliability of the grid. That is, not every remediating action 408 must be acted upon right away, though based on the network interference state generated at 406 the remediating action 408 will typically be placed in a schedule or work queue.

Validation 410 involves checking the network interference state generated at 406 against actual grid performance. For example, if a network interference state generated at 406 was that lines were sagging due to excess heat but the lines were instead sagging due to birds perched on the line, this data could be fed back at validation 410, such as by adding or a updating fingerprint database. In some embodiments a machine learning algorithm can incorporate data from validation 410 as training data.

Machine learning algorithms can also be trained, or fingerprints can be added to the fingerprint database by replicating expected electrical and mechanical interference modes and collecting sensor data. For example, lines can be moved, shaken, or heated to simulate mechanical interference modes. Similarly, electromagnetic field generation, intentionally created resonant feedback, and the like can be intentionally created in a safe environment or sandbox to simulate electrical interference modes. These fingerprints or training data can be used with, and optionally supplemented by, the information gleaned by validation 410, to increase the accuracy and geographical precision of interference detection by system 400.

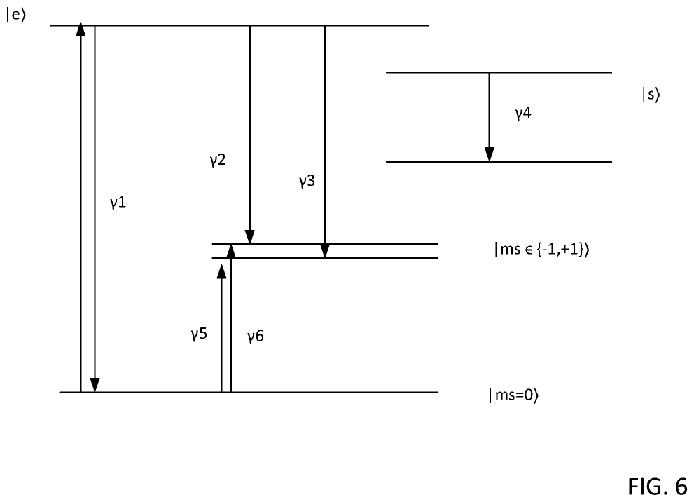

FIG. 5 shows an NV center in a carbon diamond lattice, referred to briefly above. The NV-energy structure has a triplet ground state, an excited state, and a singlet state manifold, as shown in FIG. 6. FIG. 6 uses ket notation to show the energy level corresponding to electrons in each of the ground spin state mₛ=0, an excited state |e [symbol] , and for mₛ as one of −1 and +1. The energy level of these two states is slightly different depending upon the applied field direction and strength. The number of different states corresponding to a particular energy level is known as the degree of degeneracy of the level; in the example shown in FIG. 6 there are two distinct energy levels, one for each of mₛ=±1 and mₛ=−1, distinct from the mₛ=0 energy level.

As shown in FIG. 5, a vacancy 500 is arranged in a crystal structure of carbon atoms 502. This vacancy is present due to inclusion of a color defect, namely a nitrogen atom 504. Nitrogen only has three valence electrons compared to carbon's four, and the introduction of the nitrogen atom into the structure causes the vacancy structure in which the electrons can be used for quantum sensing.

Wavelengths γ1, γ2, γ3, and γ4 are shown in FIG. 6 that correspond to the wavelength of a photon having the energy level of the gap between the energy levels shown in FIG. 6. For an NV center, by applying an off-resonant laser ˜515 nm, NV centers can be optically pumped such that they are all in the mₛ=0 state. This happens because the 515 nm laser is of higher energy than any of the possible transitions, giving access to the vibrational bands of the crystal (i.e., the energy level shown as |e [symbol] ). Other lower wavelengths could be used as well as desired. For other quantum structures, the appropriate level of energy to perform optical pumping may vary.

Initially the NV center will have some electrons in the mₛ=0 state and some in the mₛ=±1 state. The laser or other light source at or below 515 nm will excite the ground state atoms into the excited state |e [symbol] . The mₛ=0 electrons must decay back to the mₛ=0 state due to spin conservation, by emitting a ˜637 nm photon. The mₛ=±1 can decay back to the mₛ=±1 state (γ2 or γ3), or they can emit a phonon and decay through the single state manifold γ4. Based upon the wavelength of the emitted light at each of the wavelengths γ1-γ4 it is possible to determine how many electrons are entering each mₛ band.

A phonon is a quantized vibrational (sound) quasiparticle. When they decay through this phonon sideband, they decay to the mₛ=0 state while emitting a photon at wavelength γ4. This process allows for preparation of the qubits into the ground state and is useful for quantum information and quantum sensing.

The optical pumping has several consequences, one of which we will exploit in continuous wave-optically detected magnetic resonance (CW-ODMR). The excited state has a lifetime of ˜30 ns and the phonon side state has a lifetime of ˜300 ns. Since the sideband decays by emitting phonons and infrared light (˜1042 nm), when mₛ=±1 electrons go through the sideband they “go dark” and become shelved in the sideband state before decaying back to the mₛ=1 state.

When a magnetic field is applied near the NV, the degeneracy of the mₛ=±1 state is lifted and the energy levels split, according to the Zeeman Effect. The energy difference between the mₛ=0 state and the mₛ=±1 state is in the microwave range for NV centers, though it may be in a different part of the electromagnetic spectrum for other quantum structures. To perform CW-ODMR, we apply the 515 nm laser continuously, and using separate microwave antennae we sweep over our microwave frequency, as shown previously with respect to FIG. 2 (wherein light source 202 provides the continuous 515 nm light, while pulse generator 212 provides the microwave frequency sweep).

When the microwave is resonant with the mₛ=0→+1 transition, depicted as wavelengths γ5 and γ6 in FIG. 6, electrons will be first pumped to the mₛ=±1 state before the laser excites them to the excited state. They will then decay through the phonon side band and the total luminosity of the diamond will go down as these electrons “go dark” and become shelved.

The fluoresced light can be collected as shown in FIG. 2 and focused onto a detector (e.g., 210) such as a photodiode. When there is a drop in luminosity, the microwave is on resonance with one of the mₛ=±1 states. The Zeeman Effect splits the mₛ=±1 and mₛ=−1 states such that the energy splitting, A, is given by:

$$Δ = 2 γ {B}_{z}$$

Where

$$γ \approx 28 \frac{M H z}{m T}$$

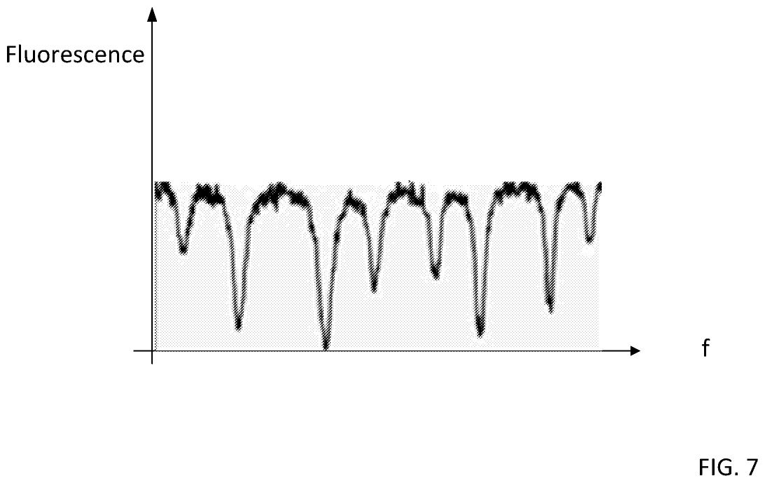

is the electron gyromagnetic ratio, and B_{z} is the magnetic field along the nitrogen-vacancy axis. Since there are 4 different orientations for vacancy 500, there will be a total of 8 resonant peaks as shown in FIG. 7. Since there is a bound on the orientation due to the tetrahedron lattice of the diamond, relatively simple geometric operations can be performed to find the total field strength B incident upon the vacancy 500. We can also observe the change in separation size of the peaks to detect changes in the applied magnetic field.

When observing a change in peak separation, all of the peaks can be analyzed or it is also possible and efficient to observe only the outermost peaks, as they will have the largest change in separation given any arbitrary δ B_{z}.

The sweep of RF signal described above is referred to as being continuous, but in some embodiments it may be spaced at intervals to provide more useful information. For example, in the United States the power grid runs on a 60 Hz AC standard. If sensing devices (e.g., 120) cycle their measurements at some arbitrary interval the sensor would be out of phase with the power line and the measurements would be hard to reconstruct and decipher. At the end of each measurement at some microwave frequency, the vacancy 500 must have a relaxation time to ensure all the electrons get optically pumped back into the mₛ=0 state. This relaxation time is dependent on NV concentration, which is why high concentration samples take longer for a full spectrum measurement. Let us call this minimum relaxation time t=τₘᵢₙ. So long as the relaxation time is set such that τ≥τₘᵢₙ the sensor will work. That means t can be adjusted so that the sensor is in phase with the power line at any arbitrary frequency.

It should be apparent from the foregoing that with sensing devices such as those described herein spread at various points along the power grid, there could be a near live-time feed of power distribution along an entire grid. If the sweep times of the various sensing devices was staggered, then there would be a continuously updating map of power grid current. The location of the sensing devices would be tied to a specific GPS coordinate such that a true map of these readings could be made.

If there was a short in the grid, such as a power outage due to a blown transformer, it would be nearly immediately detected by the sensing device and the geographic location of the source of the outage would be known to an arbitrary spatial resolution. The same would be true of an electric short, or a rapid increase in current, or any other of a variety of interferences with the operation of the grid that are either mechanical or electrical in nature. Live time, precise power measurements allow for more efficient power transfers and better allocation of power generating resources.

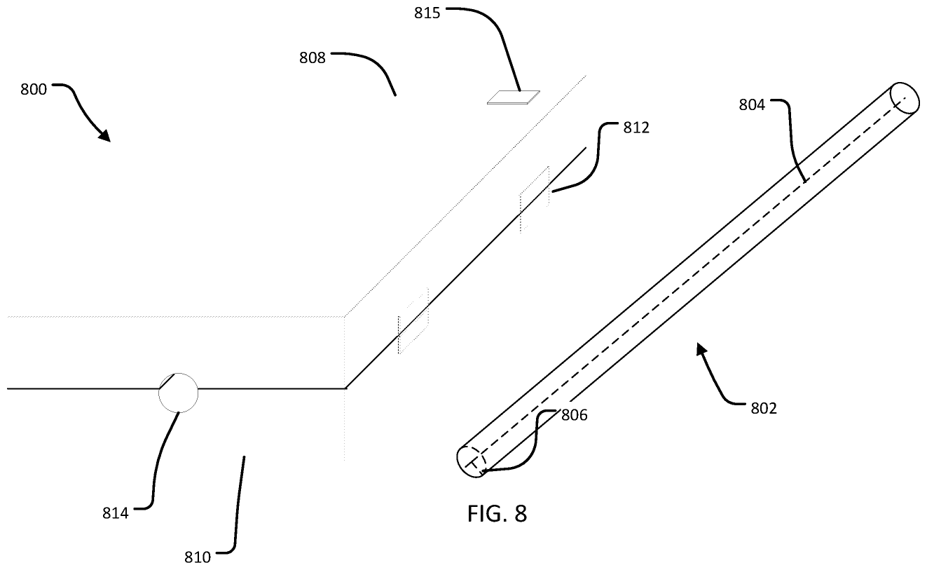

FIG. 8 is a perspective view of a sensing device 800 according to one embodiment that is configured to close around a wire 802.

Wire 802 is included merely for illustrative purposes in FIG. 8, extending along an axis 804 and having a radius 806. In various implementations, wire 802 could extend for long distances along axis 804. In some cases, such as for long-distance high-voltage transmission lines, wire 802 could extend for several miles along axis 804. Over such long distances it should be understood that axis 804 may curve somewhat, such as due to the catenoid shape of a wire supported at both ends. Over the length of device 800, however, axis 804 will be substantially straight.

Radius 804 of wire 802 is typically one of several predetermined, standard sizes. Radius 804 can be three inches, for example, for standard transmission lines in a power grid. Various sensing devices 800 can be compatible with each radius 806 of particular standard sizes of wire used in a power distribution grid.

Sensing device 800 includes a first half 808 and a second half 810 that are coupled to one another by hinges 812. First half 810 and second half 808 are shaped as two halves of a clamshell- or briefcase-shaped sensing device 800.

Three types of features are found at the intersection between first half 808 and second half 810. The first type, hinges 812, facilitate the opening and closing of this clamshell or briefcase. The second type, a fastener (not shown), can be affixed to on the opposite side of sensing device 800 from hinges 812 so that sensing device 800 can be held closed (when the fastener is closed) and can also be opened (when the fastener is open). Various fasteners could be used to accomplish this, such as physical or magnetic latches, snaps, ties, hook and loop, or various other connectors. The third feature is central channel 814.

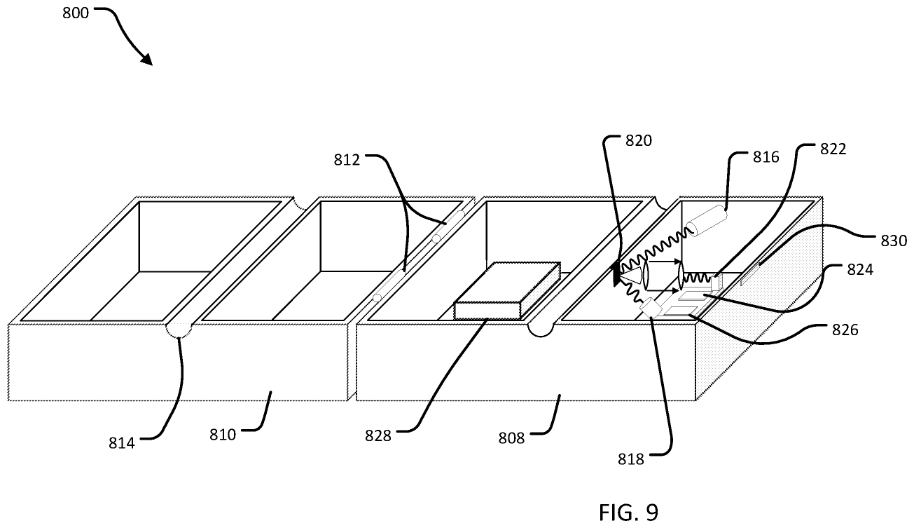

Central channel 814, as described previously with respect to FIG. 2, is shaped and sized to receive an electrical conductor (in this case, wire 802). Central channel 814 has a circular cross-section based upon the radius 806 of wire 802. Central channel extends through sensing device 800 from one end to the other, as best shown in FIG. 9, and therefore positions the conductor (i.e., wire 802) adjacent a sensor.

FIG. 8 also shows a port 815, accessible on the outside of first half 808. Port 815 provides an ingress and egress port for data, power, or both, from the outside of sensing device 800 to the inside thereof. In embodiments, port 815 can include a USB port, an NFC pad, or an aperture or access door through which battery or data storage media can be passed.

FIG. 9 shows device 800 in an open configuration, with first portion 808 rotated about hinges 812 relative to second portion 810 from the configuration shown in FIG. 8. FIG. 9 depicts central channel 814, which is partially defined within first half 808 and partially defined within second half 810. As shown in FIG. 9, first half 808 and second half 810 each have two substantially hollow rectangular prisms of space arranged on either side of the central channel 814, though in other embodiments the dimensions and contours of these open spaces can differ.

In addition to these features previously shown and described with respect to FIG. 8. FIG. 9 also shows an optical system used to detect electromagnetic field from wire 802. In particular, first half 808 includes a light source 816 and a scanning source 818 each configured to illuminate quantum structure 820. A photodetector 822 receives light emitted from quantum structure 820. Processor 824 receives a signal indicative of detected light from photodetector 822, and transmitter 826 sends the signal—or processed data based thereon—to an external location such as a central console at a power utility.

Battery 828 is arranged in the other half of first side 808 from the optical components described above. Battery 828 satisfies any power need for light source 816, scanning source 818, photodetector 822, processor 824, and transmitter 826. Though not shown in FIG. 9, appropriate wiring or other power transmission structures can be provided to connect battery 828 to light source 816, scanning source 818, photodetector 822, processor 824, and transmitter 826. Battery 828 can be arranged in either first half 808 or second half 810. Because battery 828 and any accompanying wiring often include magnetic elements and moving charges, battery 828 and any wiring may be positioned and insulated to reduce interference at quantum sensor 820.

FIG. 9 also shows one half of a magnetic latch 830 that can hold sensing device 800 in the closed configuration that is depicted in FIG. 8.

The sensing functions of device 800 are carried out as described in detail above. Briefly, light source 816 illuminates quantum structure 820 to pump electrons therein, and scanning source 818 emits lights across a spectrum of wavelengths having energy levels corresponding to different spin states of the electrons within quantum structure 820. The gap between these energy levels is based on magnetic field at quantum structure 820, such that the gap between peaks and troughs in emitted light received at photodetector 822 are a very precise measure of electrical current through an adjacent conductor.

Various light-handling structures have been previously described with respect to FIG. 2. While their description is not repeated with respect to FIG. 9, it should be understood that various mirrors, objectives, lenses, and other optical structures can be included to direct light from light source 816 and scanning source 818 to quantum structure 820. Likewise, various mirrors, objectives, lenses, and other optical structures can be included to direct light from quantum structure 820 to photodiode 822.

FIG. 9 also shows one possible arrangement of quantum structure 820 relative to central channel 814. In particular, quantum structure 820 is built into the wall of central channel 814 in FIG. 9. Because of this arrangement, and because central channel 814 is sized to correspond to the radius 806 of a particular wire 802 as described in FIG. 8, quantum structure 820 will be positioned in direct contact with the wire 802 or very close thereto. Proximity to a conductor is important in detecting current in an AC transmission line, and the arrangement shown in FIG. 9 enhances sensitivity of sensing device 800 by reducing this distance.

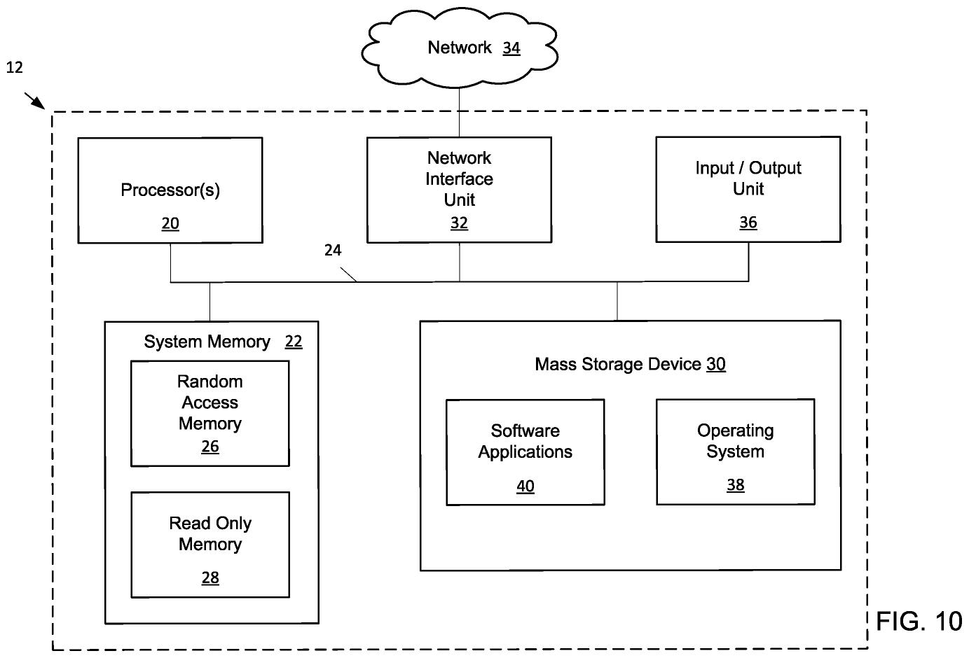

FIG. 10 schematically shows example physical components of portions of the sensing device of any of FIGS. 2 and 8-9. In particular, additional components of the sensing devices described therein are illustrated in FIG. 10.

As described with respect to FIG. 2, sensing device 120 includes a circuitboard 216. Likewise, the embodiment shown in FIGS. 8 and 9 includes a processor 824 and transmitter 826 coupled to a battery 828. FIG. 10 shows a more generalized architecture for systems that can carry out the functions of such structures. In this example, a computer hardware architecture 12 provides the computing resources to perform the functionality associated with a sensing device (FIGS. 2, 8, and 9) connected to a network of such sensing devices (FIG. 1). The sensing device 120 (FIGS. 1, 2) or sensing device 800 (FIGS. 8, 9) and other computing resources associated with the power distribution grid 100 (FIG. 1) can be similarly configured.

The computer hardware architecture 12 can be an internally controlled and managed device (or multiple devices) of a business enterprise, e.g., a utility, a financial institution, or another user of electrical service. Alternatively, the computer hardware architecture 12 can represent one or more devices operating in a shared computing system external to the enterprise or institution, such as a cloud. Further, the other computing devices disclosed herein can include the same or similar components, including the sensing device (e.g., 120, 800).

Via the network 34, the components of the computer hardware architecture 12 that are physically remote from one another can interact with one another.

The computer hardware architecture 12 includes the processor(s) 20, a system memory 22, and a system bus 24 that couples the system memory 22 to the processor(s) 20.

The system memory 22 includes a random access memory (“RAM”) 26 and a read-only memory (“ROM”) 28. A basic input/output system that contains the basic routines that help to transfer information between elements within the computer hardware architecture 12, such as during startup, is stored in the ROM 28.

The computer hardware architecture 12 further includes a mass storage device 30. The mass storage device 30 can be coupled to the circuitboard 216 (FIG. 2), as described above. The mass storage device 30 is able to store software instructions and data, such as a fingerprint database used for comparison of sensor data to fingerprints at 404 (FIG. 4).

The mass storage device 30 is connected to the processor(s) 20 through a mass storage controller (not shown) connected to the system bus 24. The mass storage device 30 and its associated computer-readable data storage media provide non-volatile, non-transitory storage for the computer hardware architecture 12. Although the description of computer-readable data storage media contained herein refers to a mass storage device, such as a hard disk or solid state disk, it should be appreciated by those skilled in the art that computer-readable data storage media can be any available non-transitory, physical device or article of manufacture from which the central display station can read data and/or instructions.

Computer-readable data storage media include volatile and non-volatile, removable and non-removable media implemented in any method or technology for storage of information such as computer-readable software instructions, data structures, program modules or other data. Example types of computer-readable data storage media include, but are not limited to, RAM, ROM, EPROM, EEPROM, flash memory or other solid state memory technology, CD-ROMs, digital versatile discs (“DVDs”), other optical storage media, magnetic cassettes, magnetic tape, magnetic disk storage or other magnetic storage devices, or any other medium which can be used to store the desired information and which can be accessed by the computer hardware architecture 12.

According to various embodiments of the invention, the computer hardware architecture 12 may operate in a networked environment using logical connections to remote network devices through the network 34, such as a wireless network, the Internet, or another type of network. The computer hardware architecture 12 may connect to the network 34 through a network interface unit 32 connected to the system bus 24. It should be appreciated that the network interface unit 32 may also be utilized to connect to other types of networks and remote computing systems. The computer hardware architecture 12 also includes an input/output unit 36 for receiving and processing input from a number of other devices, including a touch user interface display screen, an audio input device, or another type of input device. Similarly, the input/output unit 32 may provide output to a touch user interface display screen or other type of output device, or be configured to interface with drone-based recharging and data upload or retrieval systems through a port such as port 815 shown in FIG. 8.

As mentioned briefly above, the mass storage device 30 and/or the RAM 26 of the computer hardware architecture 12 can store software instructions and data. The software instructions include an operating system 38 suitable for controlling the operation of the computer hardware architecture 12. The mass storage device 30 and/or the RAM 26 also store software instructions and applications 40, that when executed by the processor(s) 20, cause the computer hardware architecture 12 to provide the functionality described above.

Embodiments of the present disclosure, for example, are described above with reference to block diagrams and/or operational illustrations of methods, systems, and computer program products. The functions/acts noted in the blocks may occur out of the order as shown in any flowchart. For example, two blocks shown in succession may in fact be executed substantially concurrently or the blocks may sometimes be executed in the reverse order, depending upon the functionality/acts involved.

The description and illustration of one or more embodiments provided in this application are not intended to limit or restrict the scope of the disclosure in any way. The embodiments, examples, and details provided in this application are considered sufficient to convey possession and enable others to make and use the disclosed embodiments. The disclosure should not be construed as being limited to any embodiment, example, or detail provided in this application. Regardless of whether shown and described in combination or separately, the various features (both structural and methodological) are intended to be selectively included or omitted to produce an embodiment with a particular set of features. Having been provided with the description and illustration of the present application, one skilled in the art may envision variations, modifications, and alternate embodiments falling within the spirit of the broader aspects of the disclosure and the general inventive concept embodied in this application that do not depart from the broader scope.

What is claimed is:

1. A sensing device for detecting a level of current in a conductor, the sensing device comprising:
a housing having a first half and a second half, wherein the first half and the second half of the housing are coupleable to one another to define a channel therebetween;
a substance made of a material having a phonon decay sideband and arranged in the housing adjacent to the channel;
a light source configured to emit a light at an energy level sufficient to excite electrons of the substance from a ground state to an energized state;
a scanning source configured to emit a scanning light, wherein the scanning light has a controllable wavelength lower than that of the light source;
one or more focusing optics arranged to receive the light from the light source and the scanning light from the scanning source and direct the light and the scanning light to the substance; and
a photodetector arranged to receive the light emanating from the substance and determine, based upon an intensity of the light as a function of the controllable wavelength of the scanning light, a magnitude of a magnetic field on the substance.

2. The sensing device of claim 1, further comprising a power supply operatively connected to the light source, the scanning source, and the photodetector.

3. The sensing device of claim 2, wherein the power supply is one or more elements chosen from a group consisting of: a rechargeable battery, a replaceable battery, and a photovoltaic cell.

4. The sensing device of claim 1, wherein the substance is a nitrogen vacancy (NV) in a carbon diamond lattice.

5. The sensing device of claim 4, wherein the scanning source is a radio frequency (RF) source.

6. The sensing device of claim 5, wherein the RF source is controllable to emit wavelengths corresponding to an energy level between:
the ground state of an electron of the substance when the electron has a spin mₛ=0, and
the energy level of the electron of the substance when the electron has a non-zero spin.

7. The sensing device of claim 6, wherein the energy level of the electron of the substance having the non-zero spin can be one of a plurality of quantized energy levels, including both a first energy level of the electron having a spin mₛ=±1, and a second energy level of the electron having a spin mₛ=−1, wherein the first energy level is different from the second energy level in the magnetic field.

8. The sensing device of claim 1, further comprising a transmitter coupled to the photodetector to transmit a signal based on a sensed magnetic field at the substance.

9. The sensing device of claim 1, wherein the substance comprises a plurality of NV centers.

10. A method for power grid management, the method comprising:
coupling a sensing device to a power transmission line, wherein the sensing device includes:
a housing having a first half and a second half, and wherein the first half and the second half of the housing are coupleable to one another to define a channel around the power transmission line therebetween;
a substance made of a material having a phonon decay sideband and arranged in the housing adjacent to the channel;
illuminating the substance with a light, the material having the phonon decay sideband, wherein with the light has an energy level sufficient to excite electrons of the substance from a ground state to an energized state;
illuminating the substance with a scanning light, wherein the scanning light has a controllable wavelength lower than that of the light;
collecting an emanated light from the substance at a photodetector; and
determining, based upon an intensity of the light as a function of the controllable wavelength of the scanning light, a magnitude of a magnetic field created by the power transmission line.

11. The method of claim 10, wherein the substance is a nitrogen vacancy (NV) in a carbon diamond lattice.

12. The method of claim 10, wherein the scanning light is produced by a radio frequency (RF) source.

13. The method of claim 12, further comprising controlling the RF source to emit wavelengths corresponding to an energy level between:
the ground state of an electron of the substance when the electron has a spin mₛ=0, and
the energy level of the electron of the substance when the electron has a non-zero spin.

14. The method of claim 10, further comprising transmitting the magnitude of the magnetic field to a remote location.

15. The method of claim 10, further comprising comparing the magnitude of the magnetic field over a time period to a plurality of fingerprints.

16. The method of claim 10, further comprising taking a remediating action to stabilize the power grid based upon the determining.

17. A system for detecting mechanical interference or electrical interference with a power distribution grid, the system comprising:
a plurality of sensing devices, each of the plurality of sensing devices comprising:
a housing having a first half and a second half, wherein the first half and the second half of the housing are coupleable to one another to define a channel therebetween;
a substance made of a material having a phonon decay sideband and arranged in the housing adjacent to the channel;
a light source configured to emit a light at an energy level sufficient to excite electrons of the substance from a ground state to an energized state;
a scanning source configured to emit a scanning light, wherein the scanning light has a controllable wavelength lower than that of the light source;
one or more focusing optics arranged to receive the light from the light source and the scanning light from the scanning source and direct the light and the scanning light to the substance;
a photodetector arranged to receive the light emanating from the substance and determine, based upon an intensity of the light as a function of the controllable wavelength of the scanning light, a magnitude of a magnetic field on the substance;
a central console communicatively coupled to each of the plurality of sensing devices to receive the determination from each of the plurality of sensing devices; and
a processor configured to detect a network interference state by comparing the determination from each of the plurality of sensing devices and carry out a remediating action based on the network interference state.

18. The system of claim 17, wherein each of the plurality of sensing devices comprises a port and each port is capable of either or both of power transfer and data transfer.

19. The system of claim 17, wherein the network interference state is determined by comparison of the determination from each of the plurality of sensing devices to a database of fingerprints.

20. The system of claim 17, wherein the network interference state is indicative of either or both of the mechanical interference and the electrical interference.
